(19) United States
(12) Patent Application Publication
(10) Pub. No.: US 2025/0373215 A1
(43) Pub. Date: Dec. 4, 2025

(54) APPARATUS AND METHODS FOR POWER AMPLIFIER CONSOLIDATION

(71) Applicant: Skyworks Solutions, Inc., Irvine, CA (US)

(72) Inventor: David Richard Pehlke, Westlake Village, CA (US)

(21) Appl. No.: 19/222,727

(22) Filed: May 29, 2025

Related U.S. Application Data
(60) Provisional application No. 63/653,612, filed on May 30, 2024.

(51) Int. Cl. H03F 3/24; H04B 1/04

(52) U.S. Cl. CPC H03F 3/245; H04B 1/04; H03F 2200/451; H04B 2001/045

(57) ABSTRACT

Apparatus and methods for power amplifier consolidation are disclosed. In certain embodiments, a power amplifier system includes a controllable attenuator that generates a 2G cellular transmit signal, a multi-throw switch including a first input that receives the 2G cellular transmit signal and a second input that receives a 5G cellular transmit signal, and a power amplifier including an input electrically connected an output of the multi-throw switch. The power amplifier amplifies the 2G cellular transmit signal in a first mode and amplifies the 5G cellular transmit signal in a second mode.

### CROSS-REFERENCE TO RELATED APPLICATIONS

This application claims the benefit of priority under 35 U.S.C. § 119 of U.S. Provisional Patent Application No. 63/653,612, filed May 30, 2024 and titled “APPARATUS AND METHODS FOR POWER AMPLIFIER CONSOLIDATION,” which is herein incorporated by reference in its entirety.

### BACKGROUND

### Technical Field

Embodiments of the invention relate to electronic systems, and in particular, to radio frequency (RF) electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about 410 MHz to about 7.125 GHz for Fifth Generation (5G) cellular communications in Frequency Range 1 (FR1) or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and wearable electronics.

### SUMMARY

In certain embodiments, the present disclosure relates to a power amplifier system. The power amplifier system includes a controllable attenuator configured to output a second generation cellular transmit signal and a multi-throw switch including a first input configured to receive the second generation cellular transmit signal, a second input configured to receive a fifth generation cellular transmit signal, and an output. The power amplifier system further includes a power amplifier including an input electrically connected the output of the multi-throw switch, the power amplifier operable to amplify the second generation cellular transmit signal in a first mode and to amplify the fifth generation cellular transmit signal in a second mode.

In various embodiments, the controllable attenuator includes a volage variable attenuator controlled by a ramping voltage. According to a number of embodiments, a waveform of the ramping voltage changes in relation to a second generation burst mask. In accordance with several embodiments, the volage variable attenuator includes a first series transistor connected between an input that receives a second generation input signal and an output that provides the second generation cellular transmit signal, a first shunt transistor connected between the input and a ground voltage and controlled by the ramping voltage, and a second shunt transistor connected between the output and the ground voltage and controlled by the ramping voltage. According to some embodiments, the volage variable attenuator includes an amplifier that uses feedback to control a control voltage of the first series transistor to provide impedance matching as the ramping voltage changes.

In several embodiments, the power amplifier system further includes a driver amplifier and a pre-power amplifier attenuator connected in series between an output of the controllable attenuator and the first input of the multi-throw switch.

In various embodiments, the second generation cellular transmit signal and the fifth generation cellular transmit signal are in a mid band frequency range.

In some embodiments, the second generation cellular transmit signal and the fifth generation cellular transmit signal are in a low band frequency range. According to several embodiments, the power amplifier system further includes a controllable load line at the output of the power amplifier, the controllable load line providing a first load line impedance in the first mode and a second load line impedance in the second mode.

In certain embodiments, the present disclosure relates to a mobile device. The mobile device includes an antenna and a front-end system including a controllable attenuator configured to output a second generation cellular transmit signal and a multi-throw switch including a first input configured to receive the second generation cellular transmit signal, a second input configured to receive a fifth generation cellular transmit signal, and an output. The controllable attenuator further includes a power amplifier including an input electrically connected the output of the multi-throw switch, the power amplifier operable to amplify the second generation cellular transmit signal in a first mode and to amplify the fifth generation cellular transmit signal in a second mode.

In various embodiments, the controllable attenuator includes a volage variable attenuator controlled by a ramping voltage. According to some embodiments, a waveform of the ramping voltage changes in relation to a second generation burst mask. In accordance with a number of embodiments, the volage variable attenuator includes a first series transistor connected between an input that receives a second generation input signal and an output that provides the second generation cellular transmit signal, a first shunt transistor connected between the input and a ground voltage and controlled by the ramping voltage, and a second shunt transistor connected between the output and the ground voltage and controlled by the ramping voltage. According to several embodiments, the volage variable attenuator includes an amplifier that uses feedback to control a control voltage of the first series transistor to provide impedance matching as the ramping voltage changes.

In a number of embodiments, the front-end system further includes a driver amplifier and a pre-power amplifier attenuator connected in series between an output of the controllable attenuator and the first input of the multi-throw switch.

In several embodiments, the second generation cellular transmit signal and the fifth generation cellular transmit signal are in a mid band frequency range.

In some embodiments, the second generation cellular transmit signal and the fifth generation cellular transmit signal are in a low band frequency range. According to a number of embodiments, the mobile device further includes a controllable load line at the output of the power amplifier, the controllable load line providing a first load line impedance in the first mode and a second load line impedance in the second mode.

In several embodiments, the mobile device further includes a transceiver configured to generate the fifth generation cellular transmit signal, a ramping voltage signal that controls the controllable attenuator, and a second generation input signal that is provided to an input of the controllable attenuator.

In certain embodiments, a method of power amplifier consolidation is provided. The method includes outputting a second generation cellular transmit signal from a controllable attenuator, receiving the second generation cellular transmit signal at a first input of a multi-throw switch, receiving a fifth generation cellular transmit signal at a second input of the multi-throw switch, and amplifying the second generation cellular transmit signal using a power amplifier in a first mode. The power amplifier includes an input electrically connected an output of the multi-throw switch. The method further includes amplifying the fifth generation cellular transmit signal using the power amplifier in a second mode.

In some embodiments, the controllable attenuator includes a volage variable attenuator controlled by a ramping voltage.

In various embodiments, a waveform of the ramping voltage changes in relation to a second generation burst mask.

In several embodiments, the volage variable attenuator includes a first series transistor connected between an input that receives a second generation input signal and an output that provides the second generation cellular transmit signal, a first shunt transistor connected between the input and a ground voltage and controlled by the ramping voltage, and a second shunt transistor connected between the output and the ground voltage and controlled by the ramping voltage. According to a number of embodiments, the volage variable attenuator includes an amplifier that uses feedback to control a control voltage of the first series transistor to provide impedance matching as the ramping voltage changes. In accordance with various embodiments, a driver amplifier and a pre-power amplifier attenuator are connected in series between an output of the controllable attenuator and the first input of the multi-throw switch.

In some embodiments, the second generation cellular transmit signal and the fifth generation cellular transmit signal are in a mid band frequency range.

In several embodiments, the second generation cellular transmit signal and the fifth generation cellular transmit signal are in a low band frequency range. According to a number of embodiments, a controllable load line is connected at the output of the power amplifier, and the controllable load line provides a first load line impedance in the first mode and a second load line impedance in the second mode.

In various embodiments, the method further includes using a transceiver to generate the fifth generation cellular transmit signal, a ramping voltage signal that controls the controllable attenuator, and a second generation input signal that is provided to an input of the controllable attenuator.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4A is a schematic diagram of one example of a communication system that operates with beamforming.

FIG. 4B is a schematic diagram of one example of beamforming to provide a transmit beam.

FIG. 4C is a schematic diagram of one example of beamforming to provide a receive beam.

FIG. 5 is a schematic diagram of one example of a burst mask for second generation (2G).

FIG. 6 is a schematic diagram of a power amplifier system with consolidation according to one embodiment.

FIG. 7 is a schematic diagram of a power amplifier system with consolidation according to another embodiment.

FIG. 8 is a schematic diagram of a front-end system with consolidation according to one embodiment.

FIG. 9 is a schematic diagram of a front-end system with consolidation according to another embodiment.

FIG. 10 is a schematic diagram of one embodiment of a mobile device.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High Power User Equipment (HPUE).

3GPP introduced Phase 1 of fifth generation (5G) technology in Release 15 and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

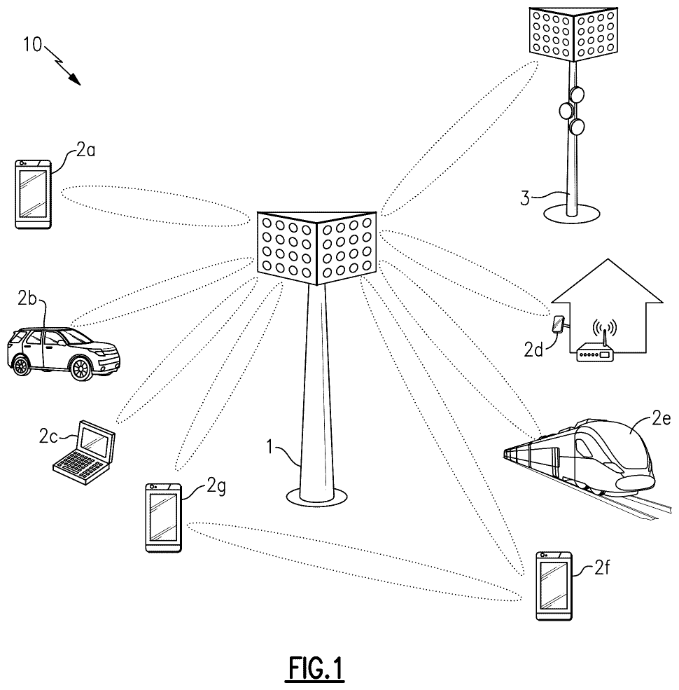

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

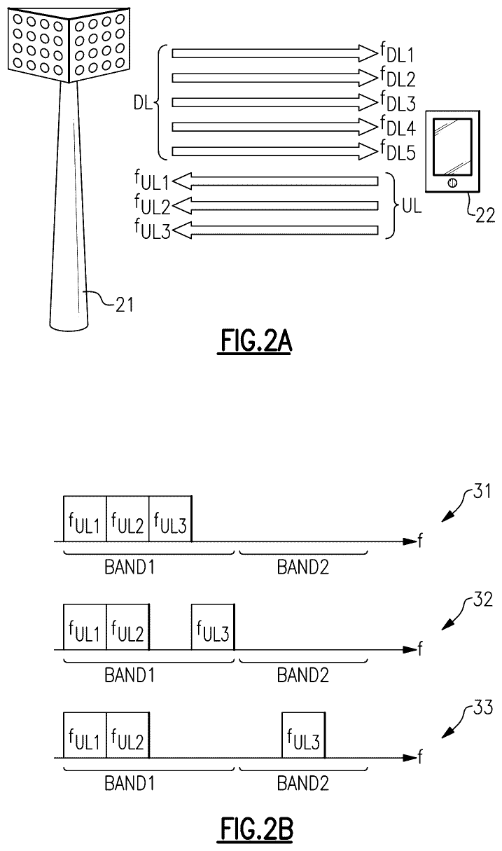

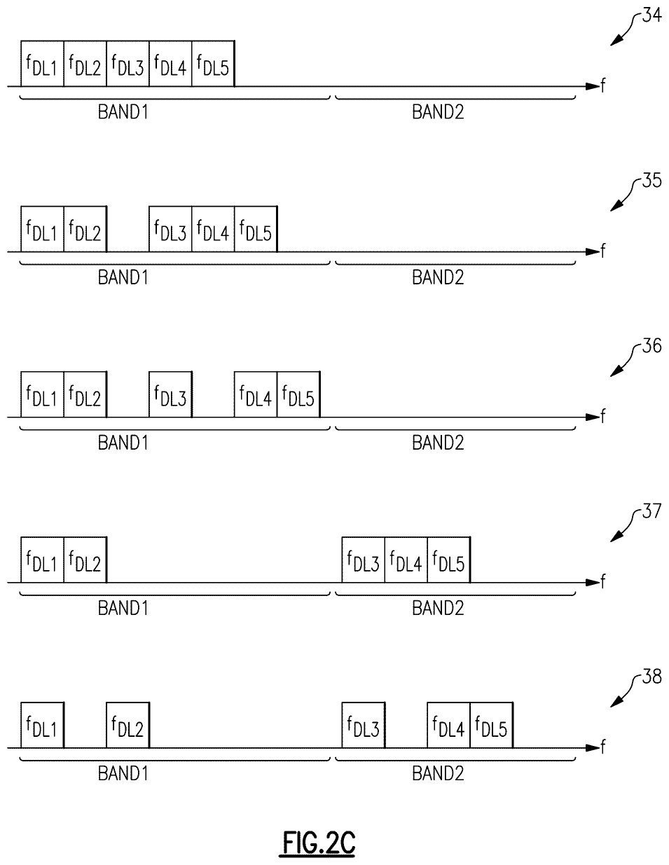

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125 MHz).

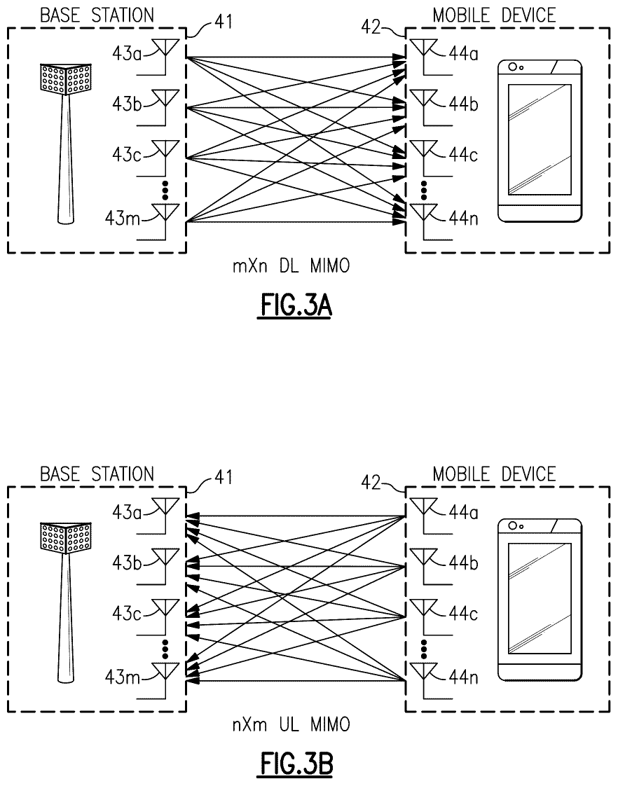

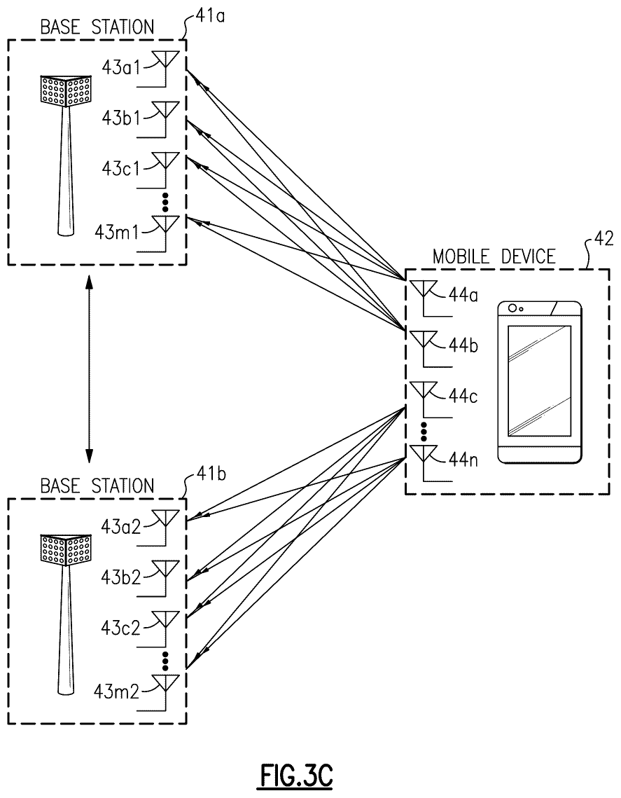

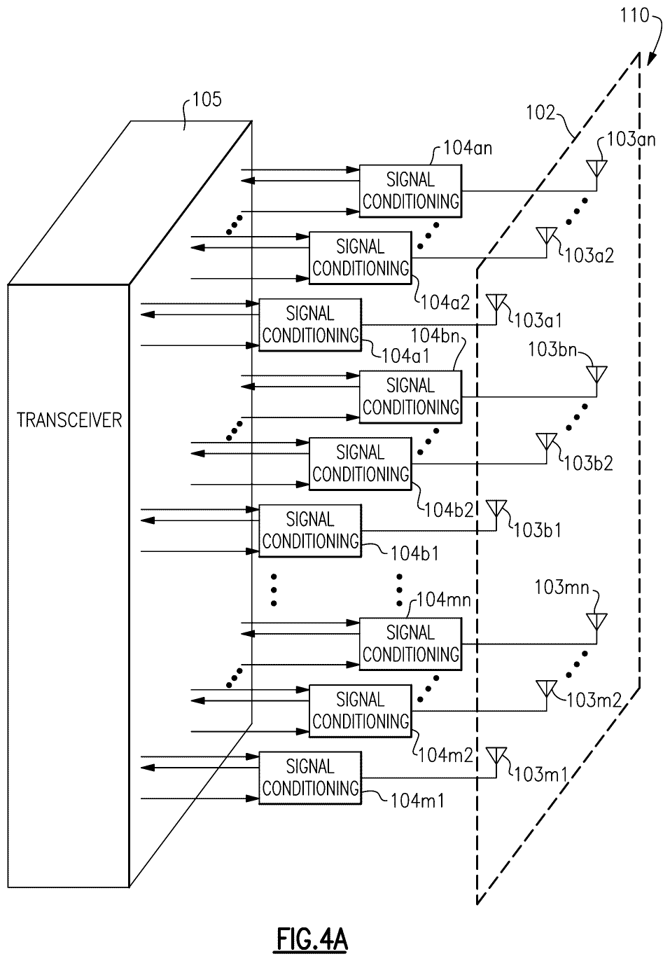

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

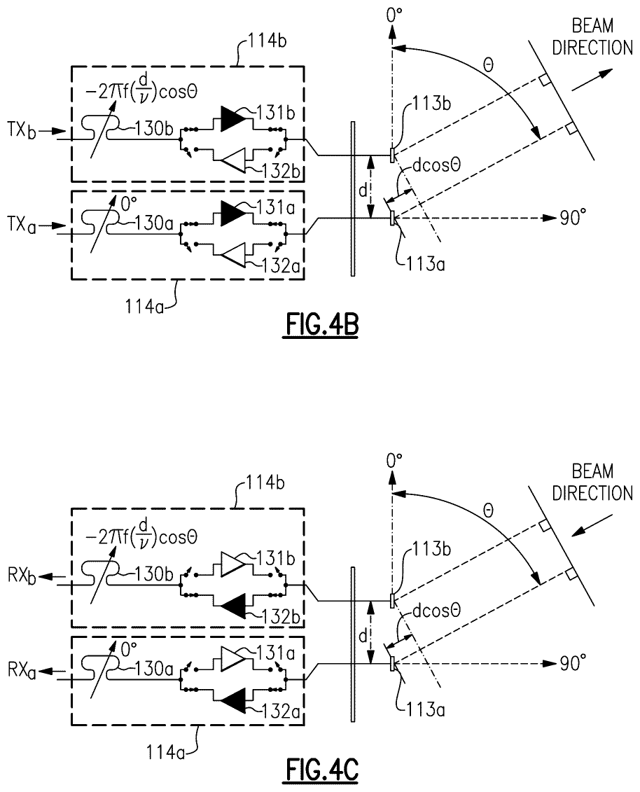

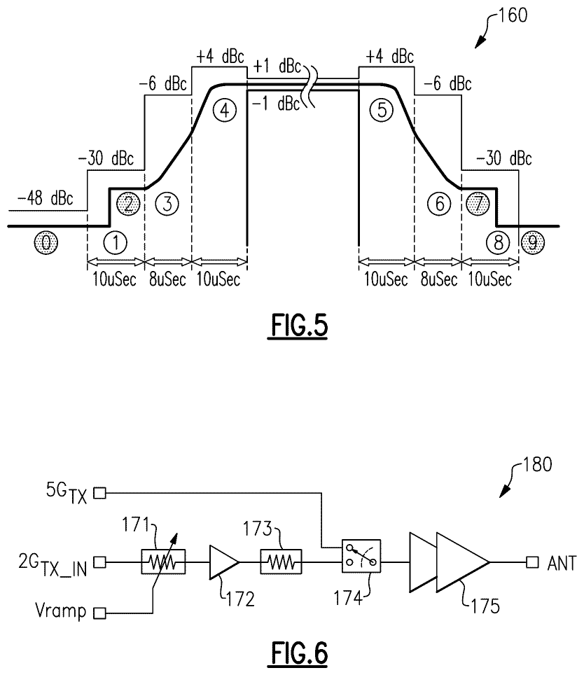

FIG. 4A is a schematic diagram of one example of a communication system 110 that operates with beamforming. The communication system 110 includes a transceiver 105, signal conditioning circuits 104a1, 104a2 . . . 104an, 104b1, 104b2 . . . 104bn, 104m1, 104m2 . . . 104mn, and an antenna array 102 that includes antenna elements 103a1, 103a2 . . . 103an, 103b1, 103b2 . . . 103bn, 103m1, 103m2 . . . 103mn.

Communications systems that communicate using millimeter wave carriers (for instance, 30 GHz to 300 GHz), centimeter wave carriers (for instance, 3 GHz to 30 GHz), and/or other frequency carriers can employ an antenna array to provide beam formation and directivity for transmission and/or reception of signals.

For example, in the illustrated embodiment, the communication system 110 includes an array 102 of m×n antenna elements, which are each controlled by a separate signal conditioning circuit, in this embodiment. As indicated by the ellipses, the communication system 110 can be implemented with any suitable number of antenna elements and signal conditioning circuits.

With respect to signal transmission, the signal conditioning circuits can provide transmit signals to the antenna array 102 such that signals radiated from the antenna elements combine using constructive and destructive interference to generate an aggregate transmit signal exhibiting beam-like qualities with more signal strength propagating in a given direction away from the antenna array 102.

In the context of signal reception, the signal conditioning circuits process the received signals (for instance, by separately controlling received signal phases) such that more signal energy is received when the signal is arriving at the antenna array 102 from a particular direction. Accordingly, the communication system 110 also provides directivity for reception of signals.

The relative concentration of signal energy into a transmit beam or a receive beam can be enhanced by increasing the size of the array. For example, with more signal energy focused into a transmit beam, the signal is able to propagate for a longer range while providing sufficient signal level for RF communications. For instance, a signal with a large proportion of signal energy focused into the transmit beam can exhibit high effective isotropic radiated power (EIRP).

In the illustrated embodiment, the transceiver 105 provides transmit signals to the signal conditioning circuits and processes signals received from the signal conditioning circuits. As shown in FIG. 4A, the transceiver 105 generates control signals for the signal conditioning circuits. The control signals can be used for a variety of functions, such as controlling the gain and phase of transmitted and/or received signals to control beamforming.

FIG. 4B is a schematic diagram of one example of beamforming to provide a transmit beam. FIG. 4B illustrates a portion of a communication system including a first signal conditioning circuit 114a, a second signal conditioning circuit 114b, a first antenna element 113a, and a second antenna element 113b.

Although illustrated as included two antenna elements and two signal conditioning circuits, a communication system can include additional antenna elements and/or signal conditioning circuits. For example, FIG. 4B illustrates one embodiment of a portion of the communication system 110 of FIG. 4A.

The first signal conditioning circuit 114a includes a first phase shifter 130a, a first power amplifier 131a, a first low noise amplifier (LNA) 132a, and switches for controlling selection of the power amplifier 131a or LNA 132a. Additionally, the second signal conditioning circuit 114b includes a second phase shifter 130b, a second power amplifier 131b, a second LNA 132b, and switches for controlling selection of the power amplifier 131b or LNA 132b.

Although one embodiment of signal conditioning circuits is shown, other implementations of signal conditioning circuits are possible. For instance, in one example, a signal conditioning circuit includes one or more band filters, duplexers, and/or other components.

In the illustrated embodiment, the first antenna element 113a and the second antenna element 113b are separated by a distance d. Additionally, FIG. 4B has been annotated with an angle θ, which in this example has a value of about 90° when the transmit beam direction is substantially perpendicular to a plane of the antenna array and a value of about 0° when the transmit beam direction is substantially parallel to the plane of the antenna array.

By controlling the relative phase of the transmit signals provided to the antenna elements 113a, 113b, a desired transmit beam angle θ can be achieved. For example, when the first phase shifter 130a has a reference value of 0°, the second phase shifter 130b can be controlled to provide a phase shift of about −2πf(d/ν) cos θ radians, where f is the fundamental frequency of the transmit signal, d is the distance between the antenna elements, ν is the velocity of the radiated wave, and x is the mathematic constant pi.

In certain implementations, the distance d is implemented to be about ½λ, where λ is the wavelength of the fundamental component of the transmit signal. In such implementations, the second phase shifter 130b can be controlled to provide a phase shift of about −π cos θ radians to achieve a transmit beam angle θ.

Accordingly, the relative phase of the phase shifters 130a, 130b can be controlled to provide transmit beamforming. In certain implementations, a baseband processor and/or a transceiver (for example, the transceiver 105 of FIG. 4A) controls phase values of one or more phase shifters and gain values of one or more controllable amplifiers to control beamforming.

FIG. 4C is a schematic diagram of one example of beamforming to provide a receive beam. FIG. 4C is similar to FIG. 4B, except that FIG. 4C illustrates beamforming in the context of a receive beam rather than a transmit beam.

As shown in FIG. 4C, a relative phase difference between the first phase shifter 130a and the second phase shifter 130b can be selected to about equal to −2πf(d/ν) cos θ radians to achieve a desired receive beam angle θ. In implementations in which the distance d corresponds to about ½λ, the phase difference can be selected to about equal to −π cos θ radians to achieve a receive beam angle θ.

Although various equations for phase values to provide beamforming have been provided, other phase selection values are possible, such as phase values selected based on implementation of an antenna array, implementation of signal conditioning circuits, and/or a radio environment.

### Examples of Consolidation of Power Amplifiers

Second generation (2G) is a legacy cellular communication standard for user equipment (UE). 2G is a digital communication standard based on time-division duplexing (TDD) in which transmit and receive are alternated. During signal transmissions, 2G transmitters in UE have specified requirements for power versus time as set forth by a burst mask of dynamic amplitude variation.

FIG. 5 is a schematic diagram of one example of a burst mask 160 for 2G. The burst mask 160 is used by 2G transmitters in UE to specify certain high output power requirements suitable for 2G transmissions as well as to limit output receive band noise for UE-to-UE coexistence.

The burst mask 160 has been annotated to depict various regions (0), (1), (2), (3), (4), (5), (6), (7), (8), and (9) that occur sequentially as part of a 2G transmission from UE. In this example, the burst mask 160 has a ramp down that is symmetric with ramp up, and thus region (5) is symmetric to region (4), region (6) is symmetric to region (3), region (7) is symmetric to region (2), region (8) is symmetric to region (1), and region (9) is symmetric to region (0).

In the depicted example, region (0) is associated with a ramping voltage (Vramp) attenuation of −42 dB, a switch isolation (SwIso)=−20 dB, a disabled power amplifier and driver (PA Enable OFF, Driver OFF), and an antenna power (P2G_Ant) less than 30-48 dBc.

With continuing reference to FIG. 5, region (1) is associated with Vramp at maximum attenuation of less than-35 dBc, an enabled power amplifier and driver (PA Enable ON, Driver ON), and a SwIso equal to 0 dB. Additionally, a total gain is −5 dB and a radio frequency integrated circuit (RFIC) or transceiver power (P_RFIC) is less than 0 dBm.

The region (2) is associated with Vramp attenuation equal to −35 dB, an enabled power amplifier and driver (PA Enable ON, Driver ON), and a SwIso equal to 0 dB. The antenna power (P2G_Ant) is equal to 0 dBm.

In the depicted example, region (3) is associated with Vramp attenuation equal to −35 dB, an enabled power amplifier and driver (PA Enable ON, Driver ON), SwIso equal to 0 dB, total gain equal to −5 dB, and P_RFIC less than 0 dBm.

With continuing reference to FIG. 5, the region (4) is associated Vramp attenuation equal to −2 dB, an enabled power amplifier and driver (PA Enable ON, Driver ON), SwIso equal to 0 dB, and P2G_Ant less than +24 dBm.

Implementation of the burst mask 160 across multiple platforms can be challenging. For example, 2G can be delivered as power ramped from the transceiver (with the power amplifier having fixed gain and bias during ramping), by power ramping the power amplifier's supply voltage (Vcc), by power ramping the power amplifier's bias, and/or using multiple techniques to efficiently ramp the power up and down to meet the burst mask specification. Such ramping techniques are incompatible, for instance, a linear 2G architecture typically cannot perform ramping using a Vramp control signal.

Conventional designs struggle with 2G design constraints and separate out an additional 2G low band (for instance, GSM850 and EGSM900) and 2G midband (for instance, DCS and PCS) solution. However, such an approach is costly to the UE design.

Apparatus and methods for power amplifier consolidation are disclosed. In certain embodiments, a power amplifier system includes a controllable attenuator that generates a 2G cellular transmit signal, a multi-throw switch including a first input that receives the 2G cellular transmit signal and a second input that receives a 5G cellular transmit signal, and a power amplifier including an input electrically connected an output of the multi-throw switch. The power amplifier amplifies the 2G cellular transmit signal in a first mode and amplifies the 5G cellular transmit signal in a second mode.

Such a solution allows 2G support to be easily populated or depopulated such that 2G support may be discontinued for mature networks and deployed for emerging networks.

Thus, a 5G power amplifier can be re-used to transmit 2G cellular signals by adding a controllable attenuator (for instance, a 2G ramping circuit) before the power amplifier's input to facilitate functional ramping (acceptable for sufficient input stage gain and dynamic range) of a burst mask for 2G.

The consolidated power amplifier systems herein can provide higher efficiency for 2G due to significant advances in efficiency of 5G power amplifier engines. Furthermore, low-cost consolidation enables a single semiconductor chip (for instance, a silicon-on-insulator die) to support 2G and thus the cost of the 2G included solution is very low.

The ramping circuit can be used to manage noise margin while allowing an existing 5G power amplifier to be repurposed for 2G transmissions. In certain implementations, the ramping circuit is implemented using a voltage variable attenuator (VVA) controlled by a ramping voltage (Vramp) signal from a transceiver.

Such power amplifier systems enable 2G in a low-cost manner by re-use of a 5G power amplifier. Such consolidation is particularly advantageous for 5G midband (MB) where the maximum power specifications well align with the 2G power requirements and receive band noise specifications are more relaxed. However, the teachings herein are also applicable to 5G power amplifiers operating over other frequency bands, such as 5G low band (LB) power amplifiers. Thus, a need for discrete 2G power amplifier modules (PAMs) can be avoided.

As persons of ordinary skill in the art will appreciate, UE for cellular networks can operate using one or more low bands (for example, RF signal bands having a frequency content of 1 GHz or less, also referred to herein as LB), one or more mid bands (for example, RF signal bands having a frequency content between 1 GHz and 2.3 GHZ, also referred to herein as MB), one or more high bands (for example, RF signal bands having a frequency content between 2.3 GHz and 3 GHZ, also referred to herein as HB), and/or other frequency bands. MHB frequency content refers to frequency content covering at least a portion of MB and at least a portion of HB, for instance, a frequency content between 1 GHz and 3 GHz.

FIG. 6 is a schematic diagram of a power amplifier system 180 with consolidation according to one embodiment. The power amplifier system 180 includes a controllable attenuator 171, a driver amplifier 172, a pre-power amplifier (pre-PA) attenuator 173, a multi-throw switch 174, and a power amplifier 175.

As shown in FIG. 6, an input of the controllable attenuator 171 receives a 2G input transmit signal 2G_{TX_IN}, and an output of the controllable attenuator 171 is connected to a first input of the multi-throw switch 174 through the driver amplifier 172 and the pre-PA attenuator 173. Additionally, a second input of the multi-throw switch 174 receives a 5G cellular transmit signal 5G_{TX}, and an output of the multi-throw switch 174 is connected to an input of the power amplifier 175. An output of the power amplifier 175 is connected to an antenna terminal ANT, which connects to an antenna either directly or indirectly through one or more front-end components.

In the illustrated embodiment, the controllable attenuator 171 includes a control input that receives a ramping voltage Vramp used to control an amount of attenuation that the controllable attenuator 171 provides to the 2G input transmit signal 2G_{TX_IN}. The ramping voltage Vramp changes over time to provide a burst mask of dynamic amplitude variation (for instance, the burst mask 160 of FIG. 5). The output of the controllable attenuator 171 provides a 2G cellular transmit signal for amplification by the power amplifier 175 when the power amplifier system 180 is operating in a 2G mode.

With continuing reference to FIG. 6, the power amplifier 175 amplifies the 5G cellular transmit signal 5G_{TX} when operating in a 5G mode. Thus, the state of the multi-throw switch 174 is controllable to provide the power amplifier 175 with the 2G cellular transmit signal or the 5G cellular transmit signal. By implementing the power amplifier system 180 in this manner, 2G can be enabled in a low-cost manner by re-use of a 5G power amplifier.

The power amplifier system 180 of FIG. 6 also includes the driver amplifier 172 and the pre-PA attenuator 173 (which can be fixed or controllable) between the output of the controllable attenuator 171 and the first input of the multi-throw switch 174, in this embodiment. Including the driver amplifier 172 and the pre-PA attenuator 173 can aid in achieving desired operating specifications (for instance, power, gain, noise, and/or linearity).

For instance, in one example implementation in which the power amplifier 175 provides amplification for a 5G MB frequency range, the power amplifier system 180 can operate with the specifications set forth in Table 1 below.

TABLE 1

| | | Controllable | Driver | Pre-PA | 5G |
|---|---|---|---|---|---|
| | RFIC | Attenuator | Amplifier | Attenuator | MB PA |
| Gain | | −2.00 | 10.00 | −3.00 | 30.00 |
| Cumulative | | −2.00 | 8.00 | 5.00 | 35.00 |
| Gain | | | | | |
| Power | −3.00 | −5.00 | 5.00 | 2.00 | 32.00 |
| Noise Figure | | 2.00 | 3.00 | 3.00 | 5.00 |
| Added Noise | −117.00 | | −111.00 | | −89.00 |
| Cumulative | −117.00 | −119.00 | −106.88 | −109.88 | −79.37 |
| Output Noise | | | | | |

As shown in the bottom-right corner of Table 1, the cumulative output noise for the 5G MB PA is less than 71 dBm/100 kHz for MB, and thus complies with cellular 5G specifications.

In the example of Table 1, the 2G MB path is specified to operate with higher gain than 5G (˜ 3 dB) and targets 30 dBm at the antenna. The standard 5G link budget for power is 24 dBm at the antenna plus 4.5 dB peak-to-average power ratio (PAPR) for 28.5 dBm peak. Additionally, the 2G path is lower post-power amplifier loss (˜1.5 dB less loss) versus, leading to a maximum power (Pmax) at the antenna of ˜30 dBm.

In the illustrated embodiment, the ramping voltage Vramp is engaged for ramp shaping for 2G. In certain implementations, at maximum amplitude, attenuator minimum is less than 2 dB and output power meets 30 dBm at the antenna. Additionally, the added noise at the output of the attenuator is less than-169 dBm/Hz, and the dynamic range is ˜40 dB (from −42 dB to −2 dB).

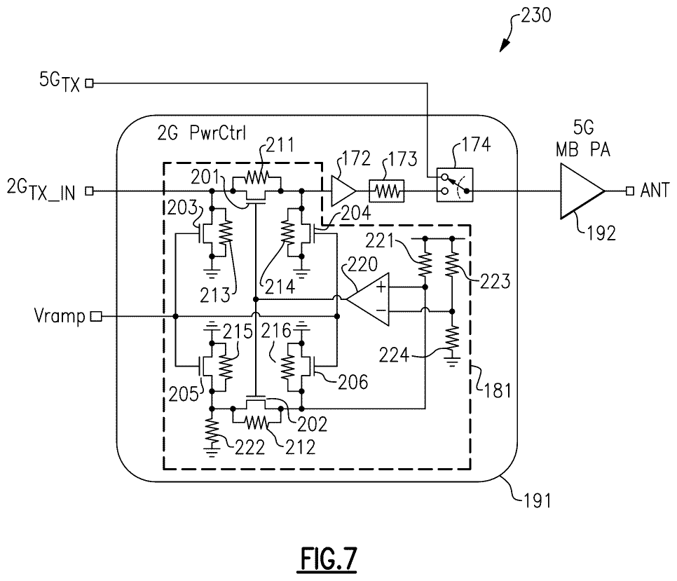

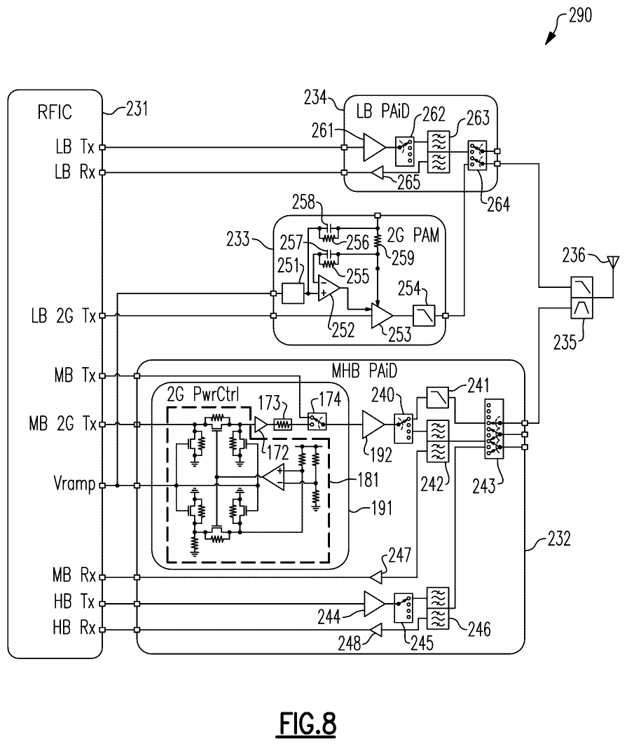

FIG. 7 is a schematic diagram of a power amplifier system 230 with consolidation according to another embodiment. The power amplifier system 230 includes a 2G MB power control circuit 191 and a 5G MB power amplifier 192. The 2G MB power control circuit 191 includes a VVA 181, a driver amplifier 172, a pre-PA attenuator 173, and a multi-throw switch 174.

As shown in FIG. 7, an input of the VVA 181 receives a MB 2G transmit input signal 2G_{TX_IN}, and an output of the VVA 181 is connected to a first input of the multi-throw switch 174 through the driver amplifier 172 and the pre-PA attenuator 173. Additionally, a second input of the multi-throw switch 174 receives a MB 5G cellular transmit signal 5G_{TX}, and an output of the multi-throw switch 174 is connected to an input of the 5G MB power amplifier 192. An output of the 5G MB power amplifier 192 is connected to an antenna terminal ANT, which connects to an antenna either directly or indirectly through one or more front-end components.

The power amplifier system 230 of FIG. 7 is similar to the power amplifier system 180 of FIG. 6, except that the power amplifier system 230 selectively operates over 2G MB or 5G MB based on a state of the multi-throw switch 174. Additionally, the power amplifier system 230 of FIG. 7 includes the VVA 181, which corresponds to a specific implementation of the controllable attenuator 171 of FIG. 6.

In the illustrated embodiment, the VVA 181 includes a first series field-effect transistor (FET) 201, a second series FET 202, a first shunt FET 203, a second shunt FET 204, a third shunt FET 205, a fourth shunt FET 206, a first channel resistor 211, a second channel resistor 212, a third channel resistor 213, a fourth channel resistor 214, a fifth channel resistor 215, a sixth channel resistor 216, an amplifier 220, a first reference resistor 221, a second reference resistor 222, a third reference resistor 223, and a fourth reference resistor 224.

As shown in FIG. 7, the first series FET 201 is electrically connected along the RF signal path of the MB 2G cellular input signal 2G_{TX_IN}. Additionally, the first shunt FET 203 is electrically connected between a source of the first series FET 201 and a ground voltage (ground), and the second shunt FET 204 is electrically connected between a drain of the first series FET 201 and ground. The first reference resistor 221, the second series FET 202, and the second reference resistor 222 are electrically connected between a reference voltage and ground. The third shunt FET 205 is electrically connected between a source of the second series FET 202 and ground, and the fourth shunt FET 206 is electrically connected between a drain of the second series FET 202 and ground. The third reference resistor 223 and the fourth reference resistor 224 are electrically connected in series between the reference voltage and ground. The first to sixth resistors 211-216 are electrically connected in parallel with the FETs 201-206, respectively.

With continuing reference to FIG. 7, a first input of the amplifier 220 is electrically connected to a node between the first reference resistor 221 and the drain of the second series FET 202. Additionally, a second input of the amplifier 220 is electrically connected to a node between the third reference resistor 223 and the fourth reference resistor 224. Furthermore, the output of the amplifier 220 is electrically connected to a gate of the first series FET 201 and to a gate of the second series FET 202. Additionally, the ramping voltage Vramp is provided to gates of the shunt FETs 203-206.

The first shunt FET 203 and the second shunt FET 204 attenuate the MB 2G cellular input signal 2G_{TX_IN} in accordance with a 2G burst mask (as indicated by the voltage waveform of the ramping voltage Vramp) to generate a MB 2G cellular transmit signal. The gate of the first series FET 201 is controlled by an output of the amplifier 220 to maintain impedance matching as the MB 2G cellular input signal 2G_{TX_IN} is attenuated.

For example, the output of the amplifier 220 is based on a difference in voltage between the first input and the second input. As the voltage of the ramping voltage Vramp is changed, the amplifier 220 adjusts the gate voltage of the second series FET 202 (which also sets the gate voltage of the first series FET 201) to maintain a matching impedance that is set based on the third and fourth reference resistors 223/224. Thus, the amplifier 220 operates with feedback to adjust the gate voltage of the second series FET 202 to account for a change in impedance arising from the attenuation provided by the shunt FETs. Such feedback achieves a matching impedance set by the third and fourth reference resistors 223/224.

FIG. 8 is a schematic diagram of a front-end system 290 with consolidation according to one embodiment. The front-end system 290 is coupled between an RFIC 231 (also referred to herein as a transceiver 231) and an antenna 236. The front-end system 290 includes a mid band and high band (MHB) module 232, a 2G power amplifier module (PAM) 233, and a LB module 234, and a diplexer 235.

The MHB module 232 includes a 2G MB power control circuit 191, a 5G MB power amplifier 192, a MB output switch 240, a MB filter 241, a MB duplexer 242, an MHB antenna switch 243, a 5G HB power amplifier 244, an HB output switch 245, an HB duplexer 246, an MB LNA 247, and an HB LNA 248. The 2G MB power control circuit 191 includes a VVA 181, a driver amplifier 172, a pre-PA attenuator 173, and a multi-throw switch 174.

As shown in FIG. 8, the MHB module 232 receives a 5G MB cellular transmit signal, a MB 2G input transmit signal, a ramping voltage Vramp, and a 5G HB cellular transmit signal from the RFIC 231. Additionally, the MHB module 232 provides a MB cellular receive signal and an HB cellular receive signal to the RFIC 231. When operating in a 2G mode, the MB output switch 240 provides the 5G MB power amplifier 192 with the MB 2G cellular transmit signal (which is generated by the attenuation of the VVA 181 in accordance with a 2G burst mask indicated by the ramping voltage Vramp). Additionally, when operating in a 5G mode, the MB output switch 240 provides the 5G MB power amplifier 192 with the MB 5G cellular transmit signal.

Thus, the 5G MB power amplifier 192 is shared for both MB 5G transmissions and MB 2G transmissions.

In certain implementations, the consolidated 5G/2G MB solution can provide 40 dB+ dynamic range, −42 dB to −2 dB over Vramp voltage range, low insertion loss (IL) at lowest attenuation <1 dB, third-order input intercept point (IIP3)>+20 dBm, harmonic generation-40 dBm, noise figure≤2 dB, and a die area (for instance, in silicon-on-insulator or SOI)<0.5 mm².

With continuing reference to FIG. 8, the 2G PAM 233 includes a ramping circuit 251, an amplifier 252, a LB 2G power amplifier 253, a LB filter 254, a first resistor 255, a second resistor 256, a first capacitor 257, a second capacitor 258, and a sense resistor 259. The voltage across the sense resistor 259 controls the input voltage difference of the amplifier 255, which adjusts a bias of the LB 2G power amplifier 253 in accordance with the ramping circuit 251.

In the illustrated embodiment, the LB module 234 includes a LB 5G power amplifier 261, a LB output switch 262, a LB duplexer 263, a LB antenna switch 264, and a LB LNA 265.

The LB 2G power amplifier 253 is not consolidated with the LB 5G power amplifier 261, in this embodiment.

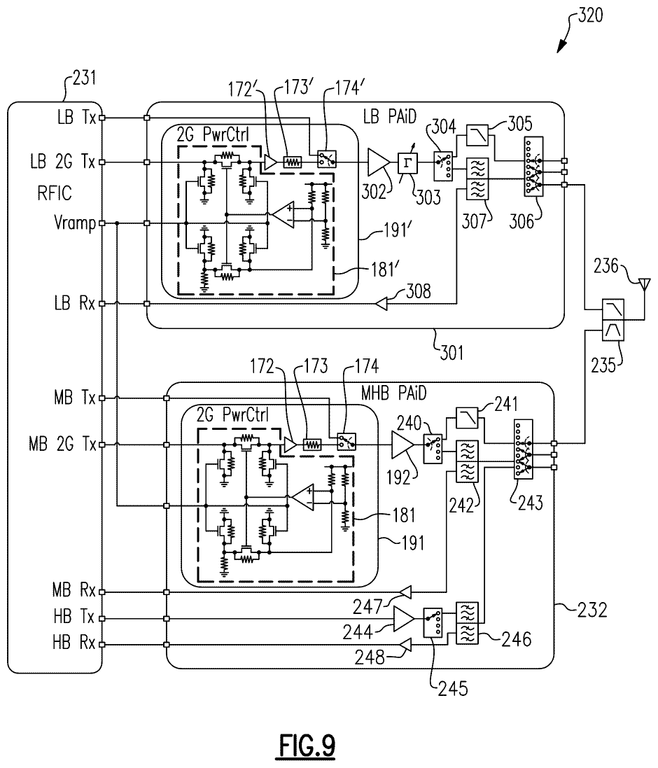

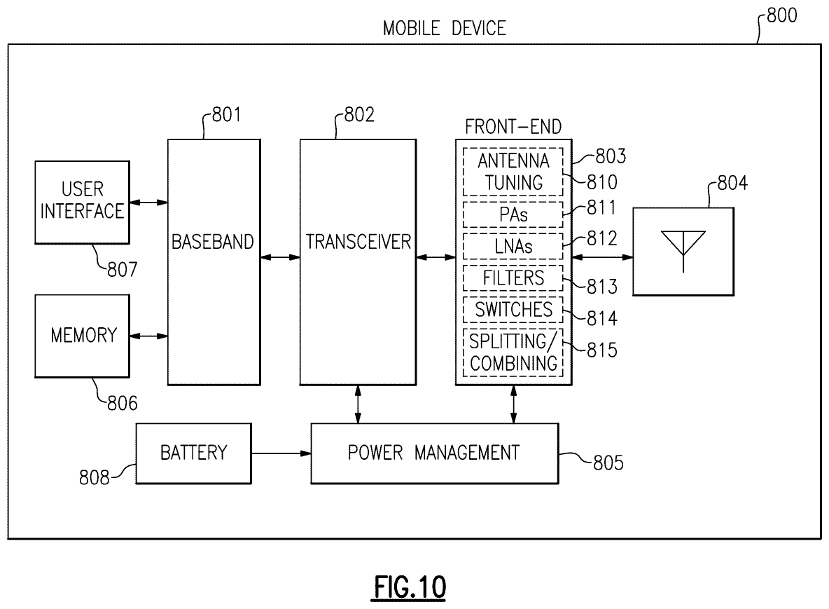

FIG. 9 is a schematic diagram of a front-end system 320 with consolidation according to another embodiment. The front-end system 320 is coupled between an RFIC or transceiver 231 and an antenna 236. The front-end system 320 includes a MHB module 232, a LB module 301, and a diplexer 235.

The front-end system 320 of FIG. 9 is similar to the front-end system 290 of FIG. 8, except that the front-end system 320 of FIG. 9 also consolidates a LB 2G power amplifier with a LB 5G power amplifier.

For example, as shown in FIG. 9, the LB module 301 includes a 2G LB power control circuit 191′ that includes a VVA 181′, a driver amplifier 172′, a pre-PA attenuator 173′, and a multi-throw switch 174′. The LB module 301 further includes a LB 5G power amplifier 302, a load adjustment circuit 303, a LB output switch 304, a LB filter 305, a LB antenna switch 306, a LB duplexer 307, and a LB LNA 308.

For LB, there is an output power misalignment for 2G versus 5G. For example, a LB 2G power amplifier is specified to operate with 33 dBm at the antenna, while a LB 5G power amplifier is specified to operate with a root-mean-square (RMS) power of 25 dBm at the antenna. Additionally, a PAPR of ˜ 4.5 dB or 29.5 dBm peak in-burst 2G power is possible, while post-PA loss is 1.5 dB less for the 2G path versus the 5G path.

Thus, the power difference is about 2 dB, with the LB 5G power amplifier being 2 dB under the 2G specification.

To account for the power difference, the illustrated embodiment includes the load adjustment circuit 303 to dynamically adjust the load (and thus the power) of the LB 5G power amplifier 302 based on whether the LB 5G power amplifier 302 is amplifying the LB 2G cellular transmit signal or the LB 5G cellular transmit signal.

However, other implementations are possible. For example, in another implementation the power difference is ignored and 2G is delivered below maximum power but still within the +2 dB/−2 dB tolerance range (about 33 dBm).

In certain implementations, the 2G LB power control circuit 191′ provides 35 dB+ dynamic range (−35 dB to 0 dB over Vramp voltage), IL at lowest attenuation <1 dB, IIP3>+30 dBm, harmonic generation<−40 dBm, minimum noise figure<1 dB, and SOI die area<0.5 mm².

FIG. 10 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. It will be understood that various functionalities associated with the transmission and receiving of RF signals can be achieved by one or more components that are collectively represented in FIG. 10 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAS) 811, low noise amplifiers (LNAs) 812, filters 813, switches 814, and signal splitting/combining circuitry 815. However, other implementations are possible. The power amplifiers 812 can include one or more power amplifiers implemented with consolidation in accordance with the teachings herein.

The front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 10, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 10, the power management system 805 receives a battery voltage from the battery 808. The battery 808 can be any suitable battery for use in the mobile device 800, including, for example, a lithium-ion battery.

### Applications

The principles and advantages of the embodiments herein can be used for any other systems or apparatus that have needs for power amplifiers. Examples of such apparatus include RF communication systems. RF communications systems include, but are not limited to, mobile phones, tablets, base stations, network access points, customer-premises equipment (CPE), laptops, and wearable electronics. Thus, the power amplifiers herein can be included in various electronic devices, including, but not limited to, consumer electronic products.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplifier system comprising:
a controllable attenuator configured to output a second generation cellular transmit signal;
a multi-throw switch including a first input configured to receive the second generation cellular transmit signal, a second input configured to receive a fifth generation cellular transmit signal, and an output; and
a power amplifier including an input electrically connected the output of the multi-throw switch, the power amplifier operable to amplify the second generation cellular transmit signal in a first mode and to amplify the fifth generation cellular transmit signal in a second mode.

2. The power amplifier system of claim 1 wherein the controllable attenuator includes a volage variable attenuator controlled by a ramping voltage.

3. The power amplifier system of claim 2 wherein a waveform of the ramping voltage changes in relation to a second generation burst mask.

4. The power amplifier system of claim 2 wherein the volage variable attenuator includes a first series transistor connected between an input that receives a second generation input signal and an output that provides the second generation cellular transmit signal, a first shunt transistor connected between the input and a ground voltage and controlled by the ramping voltage, and a second shunt transistor connected between the output and the ground voltage and controlled by the ramping voltage.

5. The power amplifier system of claim 4 wherein the volage variable attenuator includes an amplifier that uses feedback to control a control voltage of the first series transistor to provide impedance matching as the ramping voltage changes.

6. The power amplifier system of claim 1 further comprising a driver amplifier and a pre-power amplifier attenuator connected in series between an output of the controllable attenuator and the first input of the multi-throw switch.

7. The power amplifier system of claim 1 wherein the second generation cellular transmit signal and the fifth generation cellular transmit signal are in a mid band frequency range.

8. The power amplifier system of claim 1 wherein the second generation cellular transmit signal and the fifth generation cellular transmit signal are in a low band frequency range.

9. The power amplifier system of claim 8 further comprising a controllable load line at the output of the power amplifier, the controllable load line providing a first load line impedance in the first mode and a second load line impedance in the second mode.

10. A mobile device comprising:
an antenna; and
a front-end system including a controllable attenuator configured to output a second generation cellular transmit signal and a multi-throw switch including a first input configured to receive the second generation cellular transmit signal, a second input configured to receive a fifth generation cellular transmit signal, and an output, the front-end system further including a power amplifier including an input electrically connected the output of the multi-throw switch, the power amplifier operable to amplify the second generation cellular transmit signal in a first mode and to amplify the fifth generation cellular transmit signal in a second mode.

11. The mobile device of claim 10 wherein the controllable attenuator includes a volage variable attenuator controlled by a ramping voltage.

12. The mobile device of claim 11 wherein a waveform of the ramping voltage changes in relation to a second generation burst mask.

13. The mobile device of claim 11 wherein the volage variable attenuator includes a first series transistor connected between an input that receives a second generation input signal and an output that provides the second generation cellular transmit signal, a first shunt transistor connected between the input and a ground voltage and controlled by the ramping voltage, and a second shunt transistor connected between the output and the ground voltage and controlled by the ramping voltage.

14. The mobile device of claim 13 wherein the volage variable attenuator includes an amplifier that uses feedback to control a control voltage of the first series transistor to provide impedance matching as the ramping voltage changes.

15. The mobile device of claim 10 wherein the front-end system further includes a driver amplifier and a pre-power amplifier attenuator connected in series between an output of the controllable attenuator and the first input of the multi-throw switch.

16. The mobile device of claim 10 wherein the second generation cellular transmit signal and the fifth generation cellular transmit signal are in a mid band frequency range.

17. The mobile device of claim 10 wherein the second generation cellular transmit signal and the fifth generation cellular transmit signal are in a low band frequency range.

18. The mobile device of claim 17 wherein the front-end system further includes a controllable load line at the output of the power amplifier, the controllable load line providing a first load line impedance in the first mode and a second load line impedance in the second mode.

19. The mobile device of claim 10 further comprising a transceiver configured to generate the fifth generation cellular transmit signal, a ramping voltage signal that controls the controllable attenuator, and a second generation input signal that is provided to an input of the controllable attenuator.

20. A method of power amplifier consolidation, the method comprising:
outputting a second generation cellular transmit signal from a controllable attenuator;
receiving the second generation cellular transmit signal at a first input of a multi-throw switch;
receiving a fifth generation cellular transmit signal at a second input of the multi-throw switch;
amplifying the second generation cellular transmit signal using a power amplifier in a first mode, the power amplifier including an input electrically connected an output of the multi-throw switch; and
amplifying the fifth generation cellular transmit signal using the power amplifier in a second mode.

21-29. (canceled)
